(19) United States
(12) Patent Application Publication
(10) Pub. No.: US 2022/0302195 A1
(43) Pub. Date: Sep. 22, 2022

(54) SOLID-STATE IMAGING DEVICE

(71) Applicant: SONY SEMICONDUCTOR SOLUTIONS CORPORATION, KANAGAWA (JP)

(72) Inventors: HIDEKI MASUDA, KUMAMOTO (JP); NORITERU YAMADA, KUMAMOTO (JP)

(21) Appl. No.: 17/639,562

(22) PCT Filed: Jul. 6, 2020
(86) PCT No.: PCT/JP2020/026415

§ 371 Date: Mar. 1, 2022

(30) Foreign Application Priority Data
Sep. 9, 2019 (JP) 2019-163914

(51) Int. Cl. H01L 27/146; H01L 23/00

(52) U.S. Cl. CPC H01L 27/14634; H01L 27/14636; H01L 24/05; H01L 2224/04042; H01L 2224/02166; H01L 2224/48463; H01L 2224/45147; H01L 2224/05624; H01L 2224/05181; H01L 2224/05166; H01L 2224/05186; H01L 2924/04941; H01L 2924/04953; H01L 2224/05647; H01L 24/48; H01L 24/45

(57) ABSTRACT

Provided is a solid-state imaging device that suppresses propagation of a crack. There is provided a solid-state imaging device including: a first substrate on which a pixel unit configured to perform photoelectric conversion is formed; and a second substrate on which a logic circuit configured to process a pixel signal outputted from the pixel unit is formed, in which the first and second substrates are laminated by being connected by metal binding between wiring layers that are formed individually, an opening hole is formed on an outer periphery of the pixel unit to penetrate the first and second substrates to reach an upper part of a wire bonding pad formed in the second substrate, the second substrate includes an insulating layer below the wire bonding pad, and the insulating layer includes a first insulating film.

### TECHNICAL FIELD

The present technology relates to a solid-state imaging device.

### BACKGROUND ART

In a manufacturing process of a solid-state imaging device such as an image sensor, wire bonding is performed to electrically connect pads (electrodes) included in the solid-state imaging device with wires. The wire bonding is a method of connecting a wire and a pad by using heat, ultrasonic waves, pressure, or the like.

Furthermore, in a manufacturing process of a solid-state imaging device, probing for testing electrical characteristics of the solid-state imaging device is performed. The probing is a method of accurately bringing a needle into contact with a pad and transmitting a test signal to the solid-state imaging device through the needle, to confirm a response signal from the solid-state imaging device.

In the wire bonding, probing, and the like, a large stress is generated near the pad. As a result, a gap called a crack may occur in an insulating layer formed near the pad. Since this crack may become an intrusion path of moisture, it is necessary to suppress propagation of the crack.

Patent Document 1 discloses “a semiconductor device including: a first insulating film formed on a semiconductor substrate; a second insulating film formed on the first insulating film; a wiring structure embedded in the first insulating film and the second insulating film; a first dummy pattern including a first conductive layer embedded in at least a surface side of the first insulating film in the vicinity of the wiring structure; and a second dummy pattern including a second conductive layer embedded in the second insulating film in the vicinity of the wiring structure and connected to the first dummy pattern through a via hole”. This Patent Document 1 describes that this dummy pattern prevents occurrence of cracks and peeling in an interlayer insulating film interface or inside the interlayer insulating film due to a mechanical or thermal stress.

### CITATION LIST

### Patent Document

Patent Document 1: Japanese Patent Application Laid-Open No. 2004-153015

### SUMMARY OF THE INVENTION

### Problems to be Solved by the Invention

Conventionally, an insulating layer formed immediately below a pad is generally mainly includes a Si oxide film. However, since this Si oxide film has low hardness, there is a problem that a crack generated in the insulating layer propagates.

Therefore, a main object of the present technology is to provide a solid-state imaging device that suppresses propagation of a crack.

### Solutions to Problems

The present technology provides a solid-state imaging device including: a first substrate on which a pixel unit configured to perform photoelectric conversion is formed; and a second substrate on which a logic circuit configured to process a pixel signal outputted from the pixel unit is formed, in which the first and second substrates are laminated by being connected by metal binding between wiring layers that are formed individually, an opening hole is formed on an outer periphery of the pixel unit to penetrate the first and second substrates to reach an upper part of a wire bonding pad formed in the second substrate, the second substrate includes an insulating layer below the wire bonding pad, and the insulating layer includes a first insulating film.

The insulating layer may further include a second insulating film, the insulating layer may be configured by alternately laminating the first insulating film and the second insulating film in a downward direction, a part of the first insulating film may be formed on the pad side from a center of a length of the insulating layer in a downward direction, and hardness of the first insulating film may be higher than hardness of the second insulating film.

The insulating layer may be configured by alternately laminating a plurality of first insulating films and one or more second insulating films in a downward direction, a part of the first insulating film that is at least one of the plurality of first insulating films may be formed on the pad side from a center of a length of the insulating layer in a downward direction, and hardness of the first insulating film may be higher than hardness of the second insulating film.

The first insulating film may include a Si nitride film having a nitrogen content of 13 mass % or more and a carbon content of 13 mass % or more.

The first insulating film may include a Si nitride film having a nitrogen content of 50 mass % or more.

The second insulating film may include a Si oxide film having a nitrogen content of 0 to 5 mass %.

The insulating layer may be configured by laminating a first insulating film and a second insulating film in this order.

The insulating layer may be configured by laminating a second insulating film, a first insulating film, and a second insulating film in this order.

The insulating layer may be configured by laminating a first insulating film, a second insulating film, and a first insulating film in this order.

The insulating layer may be configured by laminating a second insulating film, a first insulating film, a second insulating film, a first insulating film, a second insulating film, and a first insulating film in this order.

The insulating layer may be configured by laminating a first insulating film, a second insulating film, a first insulating film, a second insulating film, and a first insulating film in this order.

The insulating layer may be configured by laminating a second insulating film, a first insulating film, a second insulating film, and a first insulating film in this order.

The insulating layer may be configured by laminating a first insulating film, a second insulating film, and a first insulating film in this order.

The insulating layer may be configured by laminating a second insulating film, a second insulating film, and a first insulating film in this order.

Moreover, the present technology provides an electronic device on which the solid-state imaging device is mounted.

### BRIEF DESCRIPTION OF DRAWINGS

FIG. 1 is a cross-sectional view for explaining a configuration of an embodiment of a solid-state imaging device according to the present technology.

FIG. 2 is a plan view for explaining a configuration of an embodiment of the solid-state imaging device according to the present technology.

FIG. 3 is a cross-sectional view for explaining a configuration of an embodiment of the solid-state imaging device according to the present technology.

FIG. 4 is a cross-sectional view for explaining a configuration of an embodiment of the solid-state imaging device according to the present technology.

FIG. 5 is a cross-sectional view for explaining a configuration of an embodiment of the solid-state imaging device according to the present technology.

FIG. 6 is a cross-sectional view for explaining a configuration of an embodiment of the solid-state imaging device according to the present technology.

FIG. 7 is a cross-sectional view for explaining a configuration of an embodiment of the solid-state imaging device according to the present technology.

FIG. 8 is a cross-sectional view for explaining a configuration of an embodiment of the solid-state imaging device according to the present technology.

FIG. 9 is a cross-sectional view for explaining a configuration of an embodiment of the solid-state imaging device according to the present technology.

FIG. 10 is a cross-sectional view for explaining a configuration of an embodiment of the solid-state imaging device according to the present technology.

FIG. 11 is a cross-sectional view for explaining a configuration of an embodiment of the solid-state imaging device according to the present technology.

FIG. 12 is a cross-sectional view for explaining a configuration of an embodiment of the solid-state imaging device according to the present technology.

FIG. 13 is a table and a graph for explaining a relationship between the number of pieces and a configuration of the insulating film according to the present technology and a stress applied to the insulating layer.

FIG. 14 is a view illustrating a usage example of a solid-state imaging device of the first to ninth embodiments to which the present technology is applied.

FIG. 15 is a diagram illustrating a configuration of an imaging device and an electronic device using a solid-state imaging device to which the present technology is applied.

FIG. 16 is a view illustrating an example of a schematic configuration of Application Example 1 (an endoscopic surgery system).

FIG. 17 is a block diagram illustrating an example of a functional configuration of a camera head and a CCU.

FIG. 18 is a block diagram illustrating an example of a schematic configuration of a vehicle control system in Application Example 2 (a mobile object).

FIG. 19 is an explanatory view illustrating an example of an installation position of a vehicle external information detection unit and an imaging unit.

### MODE FOR CARRYING OUT THE INVENTION

Preferred embodiments for implementing the present technology will be described below with reference to the drawings. Note that the embodiments described below show representative embodiments of the present technology, and do not limit the scope of the present technology.

In the following description of the embodiments, an expression with “substantially” such as substantially the same, substantially parallel, or substantially orthogonal may be used. For example, “substantially the same” means not only being completely the same, but also being substantially the same, that is, including a difference of, for example, about several percent. This similarly applies to other expressions with “substantially”. Furthermore, each figure is a schematic view, and is not necessarily strictly illustrated. Moreover, in the individual figures, substantially the same constituent elements are denoted by the same reference numerals, and redundant description may be omitted or simplified.

Note that, unless otherwise specified, in the drawings, “up” means an upward direction or an upper side in the figure, “down” means a downward direction or a lower side in the figure, “left” means a left direction or a left side in the figure, and “right” means a right direction or a right side in the figure.

The description will be given in the following order.

1. Outline of present technology

2. First embodiment (Example 1 of solid-state imaging device)

3. Second embodiment (Example 2 of solid-state imaging device)

4. Third embodiment (Example 3 of solid-state imaging device)

5. Fourth embodiment (Example 4 of solid-state imaging device)

6. Fifth embodiment (Example 5 of solid-state imaging device)

7. Sixth embodiment (Example 6 of solid-state imaging device)

8. Seventh embodiment (Example 7 of solid-state imaging device)

9. Eighth embodiment (Example 8 of solid-state imaging device)

10. Ninth embodiment (Example 9 of solid-state imaging device)

11. Verification test

12. Tenth embodiment (example of electronic device)

13. Usage example of solid-state imaging device to which present technology is applied

14. Application example of solid-state imaging device to which present technology is applied

### 1. Outline of Present Technology

First, an outline of the present technology will be described.

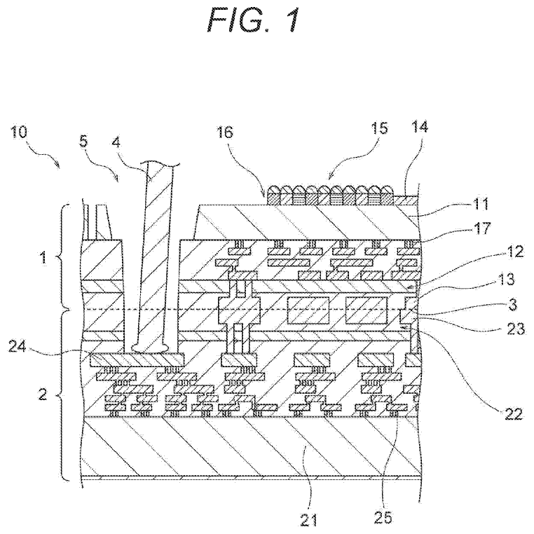

FIG. 1 is a cross-sectional view schematically illustrating a configuration of an embodiment of a solid-state imaging device according to the present technology. As illustrated in FIG. 1, a solid-state imaging device 10 includes a first substrate 1 and a second substrate 2. The first substrate 1 and the second substrate 2 are laminated. Note that a part of a wiring structure of the solid-state imaging device 10 is omitted in order to make the figure easily viewable.

In the first substrate 1, a first silicon substrate 11 is formed on one surface, and a first wiring layer 12 is formed on another surface. In the second substrate 2, a second silicon substrate 21 is formed on one surface, and a second wiring layer 22 is formed on another surface. The second wiring layer 22 is arranged so as to face the first wiring layer 12.

The first wiring layer 12 and the second wiring layer 22 are bonded at a bonding surface 3. Examples of a bonding method include plasma bonding, bonding with an adhesive, and the like.

The first silicon substrate 11 and the first wiring layer 12 are electrically connected via a first connection conductor 17. The second silicon substrate 21 and the second wiring layer 22 are electrically connected via a second connection conductor 25.

The first substrate 1 and the second substrate 2 are connected by metal binding between the wiring layers (12, 22) that are formed individually. The first wiring layer 12 and the second wiring layer 22 are electrically connected to each other via substrate connection contacts (13, 23).

In the first substrate 1 and the second substrate 2, an opening hole 5 is formed. The opening hole 5 is a hole for, for example, wire bonding to the second substrate. In the first substrate 1, the opening hole 5 is formed on an outer periphery of a pixel unit 14. The opening hole 5 penetrates the first substrate 1 and the second substrate 2 and reaches an upper part of a wire bonding pad (electrode) 24 formed in the second substrate 2. The pad 24 generally contains aluminum (Al).

The pad 24 may be made as a pad for wire bonding or probing. The wire bonding is a method of connecting the pad 24 with a wire 4 containing, for example, gold (Au) and the like, by using heat, ultrasonic waves, pressure, or the like. The probing is a method of accurately bringing a needle into contact with the pad 24 and transmitting a test signal to the semiconductor device through the needle, to confirm a response signal from the semiconductor device.

The opening hole 5 penetrates the first substrate 1 and the second substrate 2 and reaches the pad 24. Therefore, the pad 24 can be subjected to wire bonding and probing.

Note that the pad 24 may be formed in the first substrate 1. In this case, for example, it can be realized by performing a step described in WO 2015/050000 A.

Since the solid-state imaging device 10 has such a laminated structure, for example, the pixel unit 14 and the like can be formed in the first substrate 1, and a logic circuit can be formed in the second substrate 2. This configuration facilitates miniaturization and high functionality of the solid-state imaging device 10.

The first substrate 1 can include an on-chip lens 15, a color filter 16, and the pixel unit 14. The on-chip lens 15 and the color filter 16 are laminated in this order.

The on-chip lens 15 condenses light from a subject. The color filter 16 transmits light of a predetermined color in the condensed light. The pixel unit 14 can convert (photoelectrically convert) light from an outside into a pixel signal, and output.

In the first silicon substrate 11, the pixel unit 14 is formed in which a plurality of pixels is two-dimensionally arranged in a column shape. The pixel includes a photodiode (not illustrated) serving as a photoelectric conversion unit and a plurality of pixel transistors (not illustrated). Moreover, a plurality of MOS transistors (not illustrated) constituting a control circuit is formed in the first silicon substrate 11.

The photodiode is formed to have, for example, an n-type semiconductor region, and a p-type semiconductor region on a substrate surface side. The pixel transistor can include, for example, a transfer transistor, a reset transistor, an amplifier transistor, and the like. Moreover, the pixel transistor may include a selection transistor.

The logic circuit can process a pixel signal outputted from the pixel unit 14. The logic circuit can include a plurality of MOS transistors (not illustrated). The plurality of MOS transistors is connected by wiring including, for example, copper (Cu).

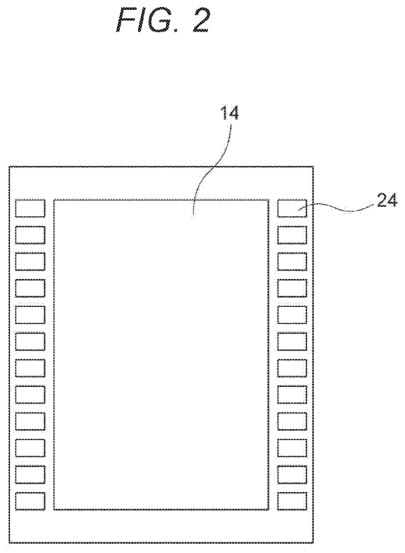

FIG. 2 is a plan view illustrating a configuration of an embodiment of the solid-state imaging device according to the present technology. As illustrated in FIG. 2, the pad 24 is formed on a side of the pixel unit 14.

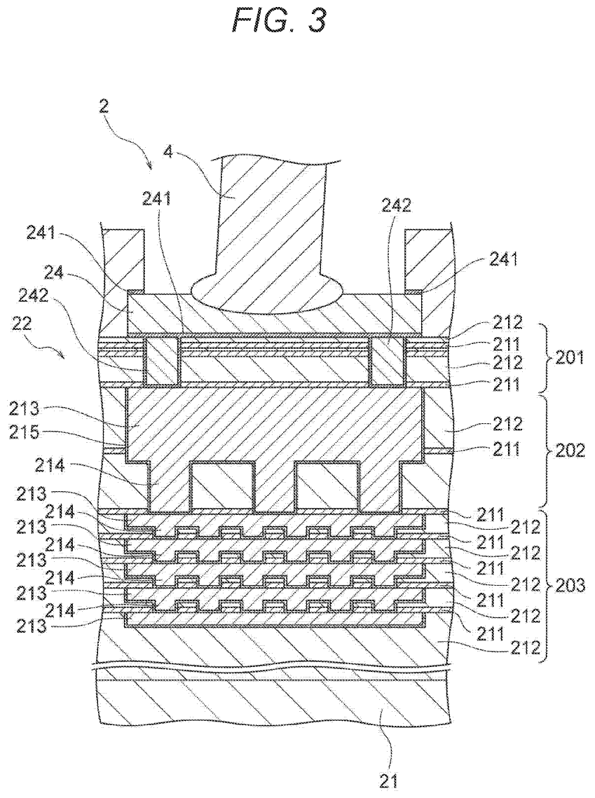

FIG. 3 is an enlarged cross-sectional view of the vicinity of the pad 24 in the cross-sectional view illustrated in FIG. 1. As illustrated in FIG. 3, the second substrate 2 includes insulating layers 201 to 203 below the pad 24.

In a first insulating layer 201, a contact 242 is formed. In a second insulating layer 202 and a third insulating layer 203, wiring 213 and a via 214 are formed.

The contact 242 connects the pad 24 and the wiring 213 formed in the second insulating layer 202. As a method of forming the contact 242, for example, the contact 242 can be formed by making a hole called a contact hole in the first insulating layer 201, and embedding tungsten in the hole.

The contact 242 generally contains Al similarly to the pad 24. In order to prevent diffusion of Al, the pad 24 and the contact 242 may be covered with a first barrier metal film 241. The first barrier metal film 241 includes, for example, Ta, Ti, TaN, TiN, or the like. Alternatively, the pad 24 or the contact 242 may contain Cu.

The wiring 213 and the via 214 generally contain Cu. In order to prevent diffusion of Cu, the wiring and the via 214 may be covered with a second barrier metal film 215. The second barrier metal film 215 includes, for example, Ta, Ti, TaN, TiN, or the like.

The insulating layers 201 to 203 are configured by laminating a first insulating film 211 and a second insulating film 212. Alternatively, the insulating layers 201 to 203 may be configured by alternately laminating a plurality of first insulating films 211 and one or more second insulating films 212 in a downward direction.

Hardness of the first insulating film 211 is higher than hardness of the second insulating film 212. This configuration can suppress propagation of a crack generated in the first insulating layer 201.

The suppression of crack propagation will be described in detail. When wire bonding or probing is performed on the pad 24, a large stress is generated near the pad 24. As a result, a crack may occur in the first insulating layer 201 formed immediately below the pad 24.

Then, since the hardness of the first insulating film 211 is higher than the hardness of the second insulating film 212, the first insulating film 211 can suppress propagation of this crack. Through trial and error, the inventors have specified hardness and components of the first insulating film 211 and the second insulating film 212 for suppressing propagation of a crack.

The hardness of the first insulating film 211 is desirably 14 to 22 GPa. The hardness of the second insulating film 212 is desirably 8 to 10 GPa. Such hardness can suppress a crack generated in the first insulating layer 201.

In order to achieve the hardness described above, the first insulating film 211 desirably includes a Si nitride film and contains SiN or SiCN. Furthermore, the second insulating film 212 desirably includes a Si oxide film, and contains SiO₂, TEOS, or SiH₄.

For example, the first insulating film 211 may include a Si nitride film (SiCN film) having a nitrogen content of 13 mass % or more and a carbon content of 13 mass % or more. A general SiCN film has hardness of 14 GPa.

Alternatively, the first insulating film 211 may include a Si nitride film (SiN film) having a nitrogen content of 50 mass % or more. A general SiN film has hardness of 22 GPa.

Furthermore, when the insulating layers 201 to 203 include a plurality of first insulating films 211, contents of nitrogen or carbon individually contained in the plurality of first insulating films 211 may be the same or different.

For example, the second insulating film 212 may include a Si oxide film having a nitrogen content of 0 to 5 mass %. General hardness of this Si oxide film is 8 to 10 GPa.

Note that, as a method of forming the insulating layers 201 to 203, for example, a chemical vapor deposition (CVD) method, a spin coating method, and the like can be used. After the film formation, the insulating layers 201 to 203 may be polished and planarized by a chemical mechanical polishing (CMP) method.

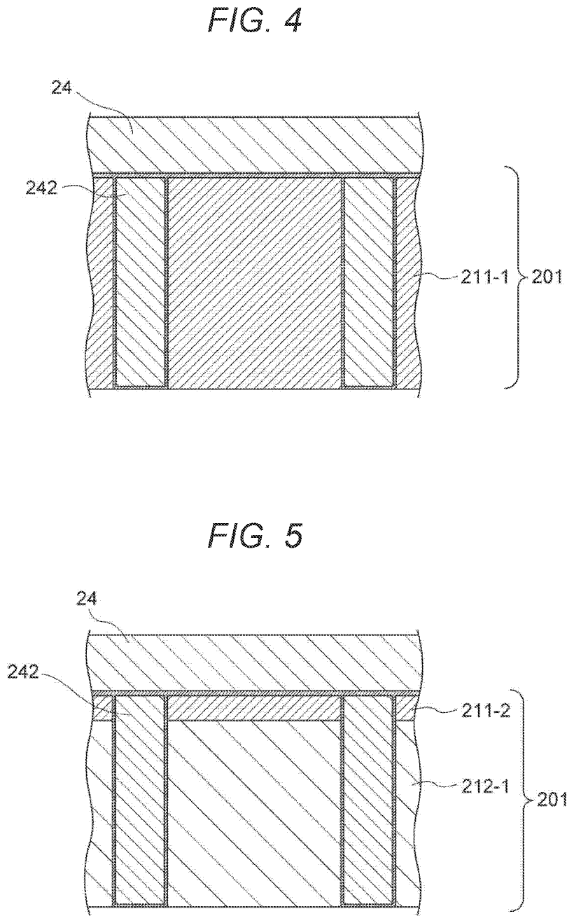

Hereinafter, with reference to FIGS. 4 to 12, a solid-state imaging device of embodiments (a first embodiment to a ninth embodiment) according to the present technology will be described concretely.

FIGS. 4 to 12 are cross-sectional views for explaining a configuration of a first insulating layer 201 in an embodiment of a solid-state imaging device according to the present technology. As illustrated in FIGS. 4 to 12, a part of at least one first insulating film 211 among a plurality of first insulating films 211 is formed on a pad 24 side from a center of a length of the first insulating layer 201 in a downward direction. More specifically, when the length of the first insulating layer 201 in the downward direction is 800 nm, a part of at least one first insulating film 211 is formed at a position within 400 nm in the downward direction from the pad 24. As a result, the first insulating film 211 can suppress propagation of a crack generated in the vicinity of the pad 24.

Moreover, the plurality of first insulating films 211 and at least one second insulating film 212 are formed by being alternately laminated in the downward direction. As a result, the plurality of first insulating films 211 can further suppress propagation of a crack.

### 2. First Embodiment (Example 1 of Solid-State Imaging Device)

As illustrated in FIG. 4, a first insulating layer 201 includes a first insulating film 211-1.

A part of the first insulating film 211-1 is formed on a pad 24 side from a center of a length of the first insulating layer 201 in the downward direction. Furthermore, the first insulating film 211-1 is arranged immediately below the pad 24. As a result, the first insulating film 211-1 can suppress a crack generated in the first insulating layer 201.

For example, the first insulating film 211-1 may include a Si nitride film (SiCN film) having a nitrogen content of 13 mass % or more and a carbon content of 13 mass % or more. At this time, hardness of the first insulating film 211-1 can be set to 14 GPa.

Alternatively, the first insulating film 211-1 may include a Si nitride film (SiN film) having a nitrogen content of 50 mass % or more. At this time, hardness of the first insulating film 211-1 can be set to 22 GPa.

### 3. Second Embodiment (Example 2 of Solid-State Imaging Device)

As illustrated in FIG. 5, a first insulating layer 201 is configured by laminating a first insulating film 211-2 and a second insulating film 212-1 in this order.

A length of the second insulating film 212-1 is longer than a length of the first insulating film 211-2 in a downward direction.

A part of the first insulating film 211-2 is formed on a pad 24 side from a center of a length of the first insulating layer 201 in the downward direction. Furthermore, the first insulating film 211-2 is arranged immediately below the pad 24. Hardness of the first insulating film 211-2 is higher than hardness of the second insulating film 212-1. As a result, the first insulating film 211-2 can suppress a crack generated in the first insulating layer 201.

Note that the length of the first insulating film 211-2 and the length of the second insulating film 212-1 in the downward direction may be different or the same.

### 4. Third Embodiment (Example 3 of Solid-State Imaging Device)

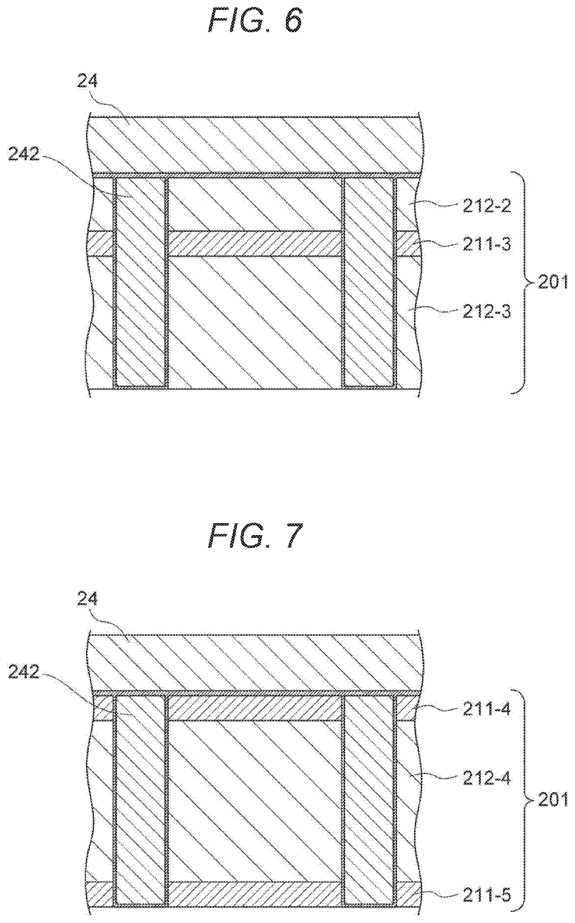

As illustrated in FIG. 6, a first insulating layer 201 is configured by laminating a second insulating film 212-2, a first insulating film 211-3, and a second insulating film 212-3 in this order.

A part of the first insulating film 211-3 is formed on a pad 24 side from a center of a length of the first insulating layer 201 in a downward direction. Hardness of the first insulating film 211-3 is higher than hardness of the second insulating film 212-2 and the second insulating film 212-3. As a result, the first insulating film 211-3 can suppress a crack generated in the first insulating layer 201.

Note that a length of the first insulating film 211-3 and a length of the second insulating film (212-2 or the like) in the downward direction may be different or the same.

### 5. Fourth Embodiment (Example 4 of Solid-State Imaging Device)

As illustrated in FIG. 7, a first insulating layer 201 is configured by laminating a first insulating film 211-4, a second insulating film 212-4, and a first insulating film 211-5 in this order.

A length of the first insulating film 211-4 and a length of the first insulating film 211-5 in a downward direction are substantially the same.

A part of the first insulating film 211-4 is formed on a pad 24 side from a center of a length of the first insulating layer 201 in the downward direction. Furthermore, the first insulating film 211-4 is arranged immediately below the pad 24. The first insulating film 211-5 is arranged immediately above a second insulating layer 202 (not illustrated). Hardness of the first insulating film 211-4 and the first insulating film 211-5 is higher than hardness of the second insulating film 212-4. As a result, the first insulating film 211-4 can suppress a crack generated in the first insulating layer 201. Moreover, a stress mitigated by the first insulating film 211-4 can be mitigated by the first insulating film 211-5.

A content of nitrogen or carbon contained in the first insulating film 211-4 and a content of nitrogen or carbon contained in the first insulating film 211-5 may be the same or different. For example, the first insulating film 211-4 may be an SiCN film, and the first insulating film 211-5 may be an SiN film.

Note that a length of the first insulating film (211-4 or the like) and a length of the second insulating film 212-4 in the downward direction may be different or the same.

Note that the second insulating film may be arranged between the pad 24 and the first insulating film 211-4, or the second insulating film may be arranged between the second insulating layer 202 (not illustrated) and the first insulating film 211-4.

### 6. Fifth Embodiment (Example 5 of Solid-State Imaging Device)

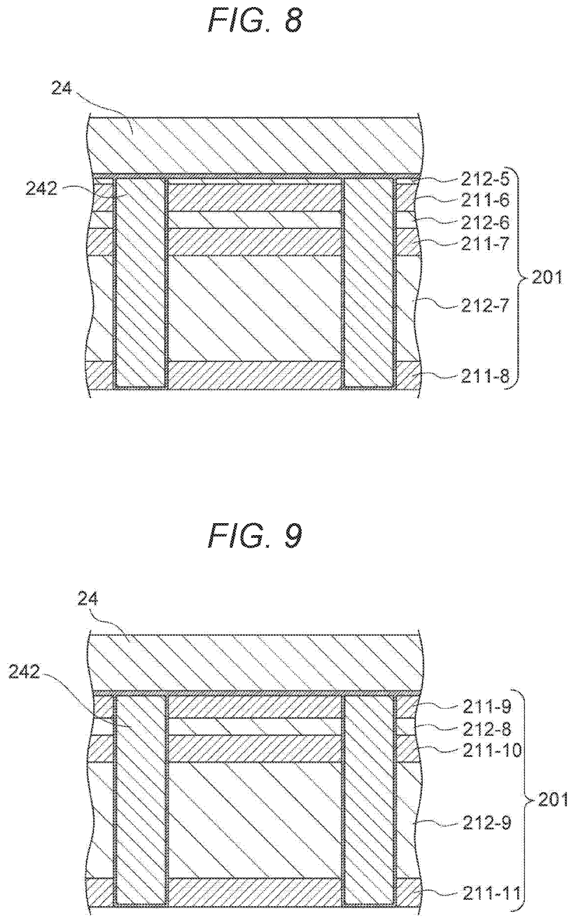

As illustrated in FIG. 8, a first insulating layer 201 is configured by laminating a second insulating film 212-5, a first insulating film 211-6, a second insulating film 212-6, a first insulating film 211-7, a second insulating film 212-7, and a first insulating film 211-8 in this order.

A length of the first insulating film 211-6, a length of the first insulating film 211-7, and a length of the first insulating film 211-8 in a downward direction are substantially the same.

A part of the first insulating film 211-6 and a part of the first insulating film 211-7 are formed on a pad 24 side from a center of a length of the first insulating layer 201 in the downward direction. The first insulating film 211-8 is arranged immediately above a second insulating layer 202 (not illustrated). Hardness of the first insulating film (211-6 or the like) is higher than that of the second insulating film (212-5 or the like). As a result, a stress mitigated by the first insulating film 211-6 can be mitigated by the first insulating film 211-7.

Moreover, a stress mitigated by the first insulating film 211-7 can be mitigated by the first insulating film 211-8.

A content of nitrogen or carbon contained in the first insulating film 211-6, a content of nitrogen or carbon contained in the first insulating film 211-7, and a content of nitrogen or carbon contained in the first insulating film 211-8 may be the same or different. For example, the first insulating film 211-6 may be a SiCN film, and the first insulating film 211-7 and the first insulating film 211-8 may be SiN films.

Note that the number of pieces of the first insulating film arranged on the pad 24 side in the first insulating layer 201 may be one or three or more. Furthermore, individual lengths of the plurality of first insulating layers in the downward direction may be the same or different.

### 7. Sixth Embodiment (Example 6 of Solid-State Imaging Device)

As illustrated in FIG. 9, a first insulating layer 201 is configured by laminating a first insulating film 211-9, a second insulating film 212-8, a first insulating film 211-10, a second insulating film 212-9, and a first insulating film 211-11 in this order.

A length of the first insulating film 211-9, a length of the first insulating film 211-10, and a length of the first insulating film 211-11 in a downward direction are substantially the same.

A part of the first insulating film 211-9 and a part of the first insulating film 211-10 are formed on a pad 24 side from a center of a length of the first insulating layer 201 in the downward direction. The first insulating film 211-11 is arranged immediately above a second insulating layer 202 (not illustrated). Hardness of the first insulating film (211-9 or the like) is higher than that of the second insulating film (212-5 or the like). As a result, a stress mitigated by the first insulating film 211-9 can be mitigated by the first insulating film 211-10.

Moreover, a stress mitigated by the first insulating film 211-10 can be mitigated by the first insulating film 211-11.

A content of nitrogen or carbon contained in the first insulating film 211-9, a content of nitrogen or carbon contained in the first insulating film 211-10, and a content of nitrogen or carbon contained in the first insulating film 211-11 may be the same or different. For example, the first insulating film 211-9 may be a SiN film, and the first insulating film 211-10 and the first insulating film 211-11 may be SiCN films.

In the first embodiment illustrated in FIG. 8, the second insulating film 212-5 is arranged between the pad 24 and the first insulating film 211-6. Whereas, in the second embodiment illustrated in FIG. 9, the pad 24 and the first insulating film 211-9 are arranged adjacent to each other. As a distance between the pad 24 and the first insulating film is shorter, the first insulating film can mitigate a stress generated in the vicinity of the pad 24. Therefore, the sixth embodiment is more preferable than the fifth embodiment.

### 8. Seventh Embodiment (Example 7 of Solid-State Imaging Device)

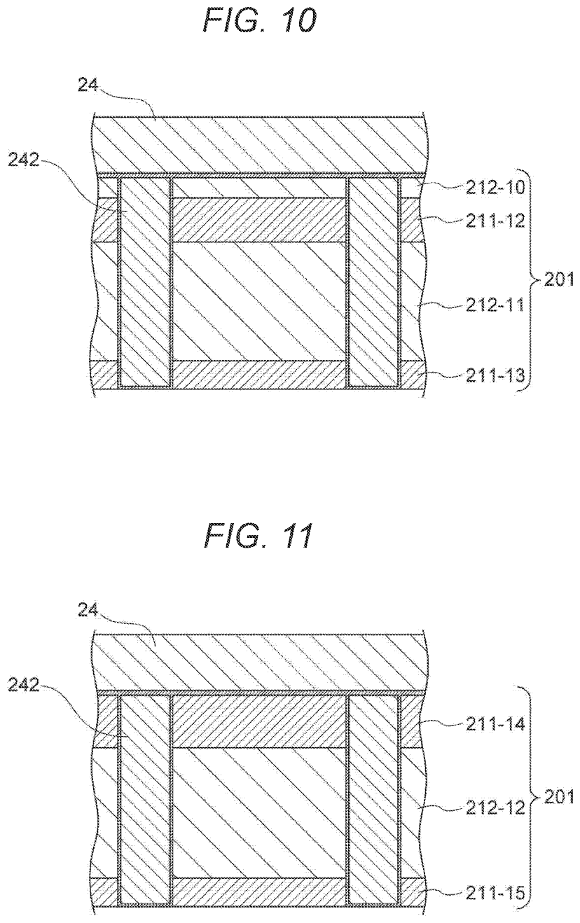

As illustrated in FIG. 10, a first insulating layer 201 is configured by laminating a second insulating film 212-10, a first insulating film 211-12, a second insulating film 212-11, and a first insulating film 211-13 in this order.

A length of the first insulating film 211-12 in a downward direction is longer than a length of the first insulating film 211-13.

The first insulating film 211-12 is arranged near a pad 24. The first insulating film 211-13 is arranged immediately above a second insulating layer 202 (not illustrated). Hardness of the first insulating film 211-12 and the first insulating film 211-13 is higher than hardness of the second insulating film (212-10 or the like). As a result, the first insulating film 211-12 can suppress a crack generated in the first insulating layer 201. Moreover, a stress mitigated by the first insulating film 211-12 can be mitigated by the first insulating film 211-13.

A content of nitrogen or carbon contained in the first insulating film 211-12 and a content of nitrogen or carbon contained in the first insulating film 211-13 may be the same or different. For example, the first insulating film 211-12 may be an SiN film, and the first insulating film 211-13 may be an SiCN film.

Note that a length of the first insulating film 211-12 and a length of the first insulating film 211-13 in the downward direction may be different or the same.

The sixth embodiment illustrated in FIG. 9 will be compared with the seventh embodiment illustrated in FIG. 10. A length of the first insulating film 211-12 in the downward direction illustrated in FIG. 10 is longer than a length of the first insulating film 211-9 in the downward direction illustrated in FIG. 9. As the length of the first insulating film in the downward direction is longer, the first insulating film can mitigate a stress. Therefore, in the seventh embodiment illustrated in FIG. 10, the number of pieces of the first insulating film arranged on an upper side is smaller than that in the sixth embodiment illustrated in FIG. 9, but the first insulating film can sufficiently mitigate a stress.

### 9. Eighth Embodiment (Example 8 of Solid-State Imaging Device)

As illustrated in FIG. 11, a first insulating layer 201 is configured by laminating a first insulating film 211-14, a second insulating film 212-12, and a first insulating film 211-15 in this order.

A length of the first insulating film 211-14 in a downward direction is longer than a length of the first insulating film 211-15.

The first insulating film 211-14 is arranged immediately below a pad 24. The first insulating film 211-15 is arranged immediately above a second insulating layer 202 (not illustrated). Hardness of the first insulating film 211-14 and the first insulating film 211-15 is higher than hardness of the second insulating film 212-12. As a result, the first insulating film 211-14 can suppress a crack generated in the first insulating layer 201. Moreover, a stress mitigated by the first insulating film 211-14 can be mitigated by the first insulating film 211-15.

A content of nitrogen or carbon contained in the first insulating film 211-14 and a content of nitrogen or carbon contained in the first insulating film 211-15 may be the same or different. For example, the first insulating film 211-14 may be an SiCN film, and the first insulating film 211-15 may be an SiN film.

Note that the length of the first insulating film 211-14 and the length of the first insulating film 211-15 in the downward direction may be different or the same.

In the seventh embodiment illustrated in FIG. 10, the second insulating film 212-10 is arranged between the pad 24 and the first insulating film 211-12. Whereas, in the eighth embodiment illustrated in FIG. 11, the pad 24 and the first insulating film 211-14 are arranged adjacent to each other. As a distance between the pad 24 and the first insulating film is shorter, the first insulating film can mitigate a stress generated in the vicinity of the pad 24. Therefore, the eighth embodiment is more preferable than the seventh embodiment.

### 10. Ninth Embodiment (Example 9 of Solid-State Imaging Device)

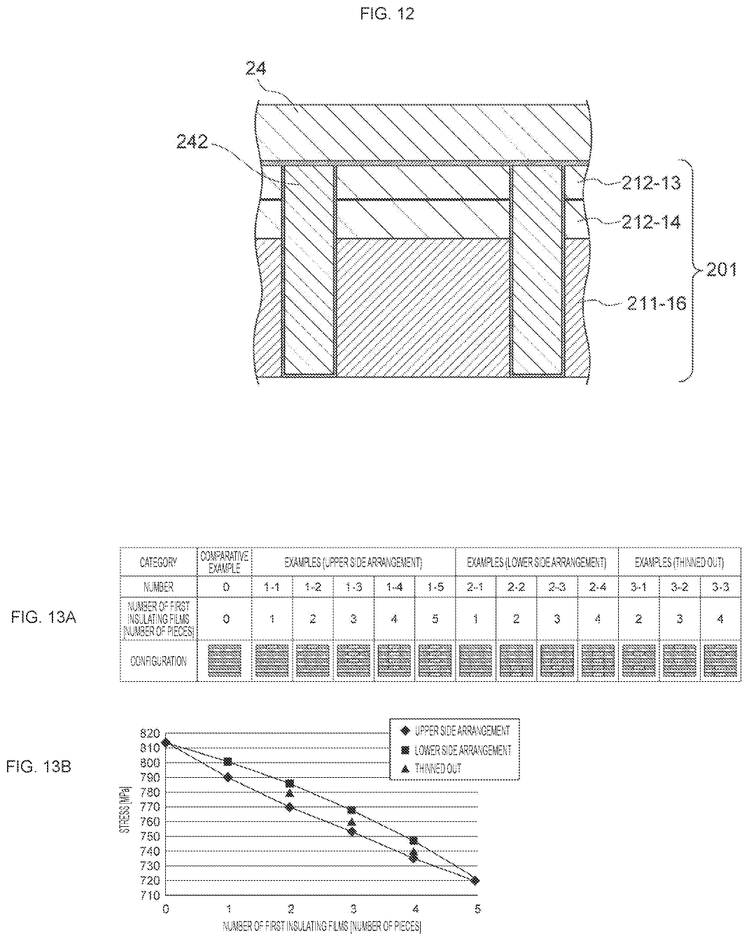

As illustrated in FIG. 12, a first insulating layer 201 is configured by laminating a second insulating film 212-13, a second insulating film 212-14, and a first insulating film 211-16 in this order.

A length of the second insulating film 212-13 and a length of the second insulating film 212-14 in a downward direction are substantially the same. A length of the first insulating film 211-16 in the downward direction is longer than a length of the second insulating film (211-13 or the like).

The first insulating film 211-16 is arranged immediately above a second insulating layer 202 (not illustrated). A part of the first insulating film 211-16 is formed on a pad 24 side from a center of a length of the first insulating layer 201 in the downward direction. Hardness of the first insulating film 211-16 is higher than hardness of the second insulating film (212-13 or the like). As a result, the first insulating film 211-16 can suppress a crack generated in the first insulating layer 201.

Note that the length of the first insulating film 211-16 and the length of the second insulating film (211-13 or the like) in the downward direction may be different or the same.

### 11. Verification Test

Here, with reference to FIG. 13, a description is given to a verification test result of a relationship between the number of pieces and a configuration of the first insulating film having high hardness and a stress mitigated by this film in the insulating layer. FIG. 13 is a table and a graph showing the relationship between the number of pieces and the configuration of the first insulating film and a stress applied to the insulating layer.

FIG. 13A illustrates the number of pieces of the first insulating film in the insulating layer, a position (a configuration) where the first insulating film is arranged, and a stress applied to the insulating layer. Moreover, a reduction amount (effect) of the stress when compared with a configuration not including the first insulating film (Comparative Example, No. 0) is illustrated.

Numbers 1-1 to 1-5 are examples of a configuration in which the first insulating film is laminated on an upper side (the pad side) of the insulating layer. Numbers 2-1 to 2-4 are examples of a configuration in which the first insulating film is laminated on a lower side of the insulating layer. Numbers 3-1 to 3-3 are examples of a configuration in which the first insulating film is thinned out and laminated in the insulating layer.

For example, in No. 1-3, the number of the first insulating films is 3. The insulating layer is configured by laminating a first insulating film, a first insulating film, a first insulating film, a second insulating film, and a second insulating film in this order. The stress applied to the insulating layer is 752 MPa. The effect is −62 MPa.

For example, in No. 3-2, the number of the first insulating films is 3. The insulating layer is configured by laminating a first insulating film, a second insulating film, a first insulating film, a second insulating film, and a first insulating film in this order. The stress applied to the insulating layer is 760 MPa. The effect is −54 MPa.

In FIG. 13B, a horizontal axis represents the number of pieces of the first insulating film, and a vertical axis represents a stress applied to the insulating layer. The number of pieces and the stress of the first insulating film are shown individually for Examples (No. 1-1 to No. 1-5) of the configuration in which the first insulating film is laminated on the upper side, Examples (No. 2-1 to No. 2-4) of the configuration in which the first insulating film is laminated on the lower side, and Examples (No. 3-1 to No. 3-3) of the configuration in which the first insulating film is thinned out and laminated in the insulating layer.

A case where the two first insulating films are arranged on the upper side (No. 1-3) and a case where the two first insulating films are arranged on the lower side (No. 2-2) will be compared and described. In the case of arrangement on the upper side, the stress applied to the insulating layer is 770 MPa, and the effect is −44 Ma. Whereas, in the case of arrangement on the lower side, the stress applied to the insulating layer is 786 MPa, and the effect is −28 MPa. That is, by arranging the first insulating film near the pad, the stress applied to the insulating layer is mitigated. As a result, generation or propagation of a crack can be suppressed.

More specifically, in a case where three first insulating films are arranged on the lower side (No. 2-3), the stress applied to the insulating layer is 769 MPa. This stress is equivalent to the stress of 770 MPa applied to the insulating layer in the case where two first insulating films are arranged on the upper side (No. 1-2). That is, even if the number of the first insulating films is small, it is possible to obtain an effect equivalent to that in a case where the number of the first insulating films is large, by devising the arrangement of the first insulating films.

### 12. Tenth Embodiment (Example of Electronic Device)

An electronic device of a tenth embodiment according to the present technology is an electronic device equipped with the solid-state imaging device of any one of the first to ninth embodiments according to the present technology. Hereinafter, the electronic device of the tenth embodiment according to the present technology will be described in detail.

### 13. Usage Example of Solid-State Imaging Device to which Present Technology is Applied

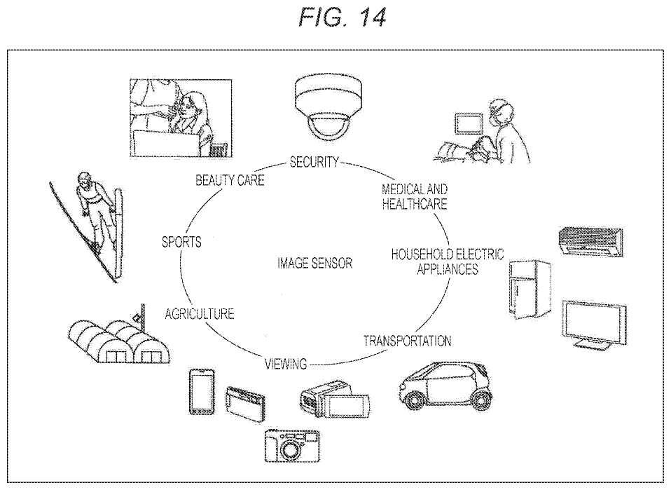

FIG. 14 is a view illustrating a usage example, as an image sensor, of the solid-state imaging device of the first to ninth embodiments according to the present technology.

The solid-state imaging device of the first to ninth embodiments described above can be used in various cases for sensing light such as visible light, infrared light, ultraviolet light, and X-ray, as described below, for example. That is, as illustrated in FIG. 14, the solid-state imaging device of any one of the first to ninth embodiments can be used for devices (for example, the electronic device of the eighth embodiment described above) used in, for example, a field of viewing where images to be used for viewing are captured, a field of transportation, a field of household electric appliances, a field of medical and healthcare, a field of security, a field of beauty care, a field of sports, a field of agriculture, and the like.

Specifically, in the field of viewing, the solid-state imaging device of any one of the first to ninth embodiments can be used for devices to capture an image to be used for viewing, for example, such as a digital camera, a smartphone, or a mobile phone with a camera function.

In the field of transportation, for example, for safe driving such as automatic stop, recognition of a state of a driver, and the like, the solid-state imaging device of any one of the first to ninth embodiments can be used for devices used for transportation, such as vehicle-mounted sensors that capture an image in front, rear, surroundings, interior, and the like of an automobile, monitoring cameras that monitor traveling vehicles and roads, and distance measurement sensors that measure a distance between vehicles.

In the field of household electric appliances, for example, in order to capture an image of a user's gesture and operate a device in accordance with the gesture, the solid-state imaging device of any one of the first to ninth embodiments can be used for devices used in household electric appliances such as TV receivers, refrigerators, and air conditioners.

In the field of medical and healthcare, for example, the solid-state imaging device of any one of the first to ninth embodiments can be used for devices used for medical and healthcare, such as endoscopes and devices that perform angiography by receiving infrared light.

In the field of security, for example, the solid-state imaging device of any one of the first to ninth embodiments can be used for devices used for security such as monitoring cameras for crime suppression and cameras for personal authentication.

In the field of beauty care, for example, the solid-state imaging device of any one of the first to ninth embodiments can be used for devices used for beauty care such as skin measuring instruments for image capturing of skin, and microscopes for image capturing of a scalp.

In the field of sports, for example, the solid-state imaging device of any one of the first to ninth embodiments can be used for devices used for sports such as action cameras and wearable cameras for sports applications and the like.

In the field of agriculture, for example, the solid-state imaging device of any one of the first to ninth embodiments can be used for devices used for agriculture such as cameras for monitoring conditions of fields and crops.

The solid-state imaging device according to any one of the first to ninth embodiments can be applied to various electronic devices such as, for example, an imaging device such as a digital still camera and a digital video camera, a mobile phone with an imaging function, or other devices having an imaging function.

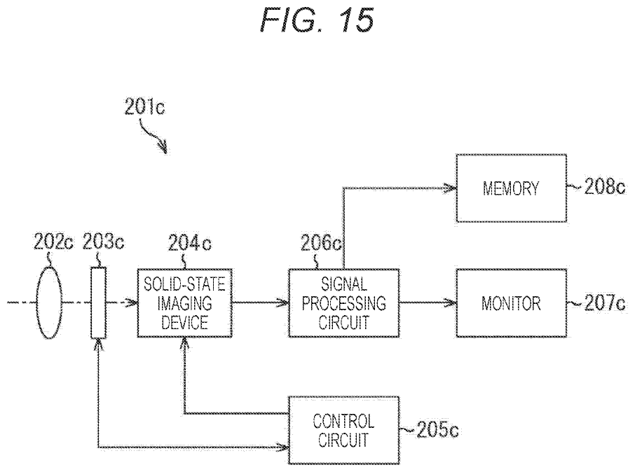

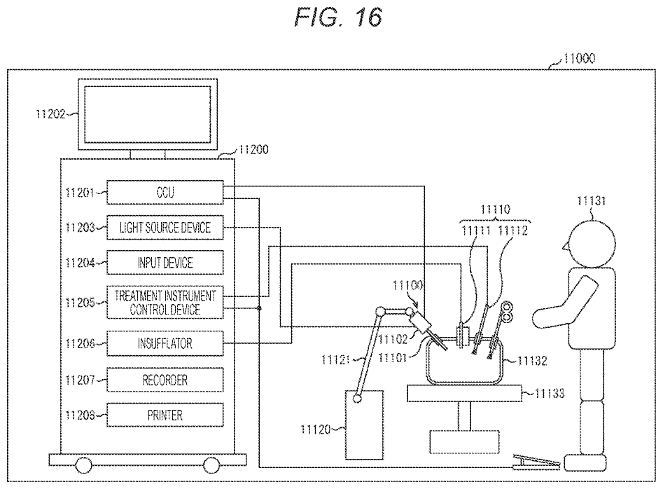

FIG. 15 is a block diagram illustrating a configuration example of an imaging device as an electronic device to which the present technology is applied.

An imaging device 201c illustrated in FIG. 15 includes an optical system 202c, a shutter device 203c, a solid-state imaging device 204c, a drive circuit (a control circuit) 205c, a signal processing circuit 206c, a monitor 207c, and a memory 208c, and can capture still images and moving images.

The optical system 202c has one or more lenses, and guides light (incident light) from a subject to the solid-state imaging device 204c and forms as an image on a light receiving surface of the solid-state imaging device 204c.

The shutter device 203c is arranged between the optical system 202c and the solid-state imaging device 204c, and controls a light irradiation period and a shading period of the solid-state imaging device 204c in accordance with the control of the drive circuit (the control circuit) 205c.

The solid-state imaging device 204c accumulates signal charges for a certain period of time in accordance with light formed as an image on the light receiving surface via the optical system 202c and the shutter device 203c. The signal charges accumulated in the solid-state imaging device 204c are transferred in accordance with a drive signal (a timing signal) supplied from the drive circuit (the control circuit) 205c.

The drive circuit (the control circuit) 205c outputs a drive signal for controlling a transfer operation of the solid-state imaging device 204c and a shutter operation of the shutter device 203c, to drive the solid-state imaging device 204c and the shutter device 203c.

The signal processing circuit 206c performs various kinds of signal processing on the signal charges outputted from the solid-state imaging device 204c. An image (image data) obtained by performing signal processing by the signal processing circuit 206c is supplied to the monitor 207c to be displayed, or supplied to the memory 208c to be stored (recorded).

### 14. Application Example of Solid-State Imaging Device to which Present Technology is Applied

Hereinafter, an application example (Application Examples 1 and 2) of the solid-state imaging device (the image sensor) described in the above-described first to fourth embodiments will be described. Any of the solid-state imaging devices in the above-described embodiments and the like can be applied to electronic devices in various fields. Here, as an example, an endoscopic surgery system (Application Example 1) and a mobile object (Application Example 2) will be described. Note that the imaging device described in the section <8. Usage example of solid-state imaging device to which present technology is applied> described above is also one of application examples of the solid-state imaging device (the image sensor) described in the first to fourth embodiments according to the present technology.

### Application Example 1

### Application Example to Endoscopic Surgery System

The present technology can be applied to various products. For example, the technology (the present technology) according to the present disclosure may be applied to an endoscopic surgery system.

FIG. 16 is a view illustrating an example of a schematic configuration of an endoscopic surgery system to which the technology (the present technology) according to the present disclosure can be applied.

FIG. 16 illustrates a state where an operator (a doctor) 11131 performs surgery on a patient 11132 on a patient bed 11133, by using an endoscopic surgery system 11000. As illustrated, the endoscopic surgery system 11000 includes: an endoscope 11100; other surgical instruments 11110 such as an insufflation tube 11111 and an energy treatment instrument 11112; a support arm device 11120 supporting the endoscope 11100; and a cart 11200 mounted with various devices for endoscopic surgery.

The endoscope 11100 includes a lens barrel 11101 whose region of a predetermined length from a distal end is inserted into a body cavity of the patient 11132, and a camera head 11102 connected to a proximal end of the lens barrel 11101. In the illustrated example, the endoscope 11100 configured as a so-called rigid endoscope having a rigid lens barrel 11101 is illustrated, but the endoscope 11100 may be configured as a so-called flexible endoscope having a flexible lens barrel.

At the distal end of the lens barrel 11101, an opening fitted with an objective lens is provided. The endoscope 11100 is connected with a light source device 11203, and light generated by the light source device 11203 is guided to the distal end of the lens barrel by a light guide extended inside the lens barrel 11101, and emitted toward an observation target in the body cavity of the patient 11132 through the objective lens. Note that the endoscope 11100 may be a forward-viewing endoscope, or may be an oblique-viewing endoscope or a side-viewing endoscope.

Inside the camera head 11102, an optical system and an imaging element are provided, and reflected light (observation light) from the observation target is condensed on the imaging element by the optical system. The observation light is photoelectrically converted by the imaging element, and an electric signal corresponding to the observation light, in other words, an image signal corresponding to an observation image is generated. The image signal is transmitted to a camera control unit (CCU) 11201 as RAW data.

The CCU 11201 is configured by a central processing unit (CPU), a graphics processing unit (GPU), and the like, and integrally controls action of the endoscope 11100 and a display device 11202. Moreover, the CCU 11201 receives an image signal from the camera head 11102, and applies, on the image signal, various types of image processing for displaying an image on the basis of the image signal, for example, development processing (demosaicing processing) and the like.

The display device 11202 displays an image on the basis of the image signal subjected to the image processing by the CCU 11201, under the control of the CCU 11201.

The light source device 11203 is configured by a light source such as a light emitting diode (LED), for example, and supplies irradiation light at a time of capturing an image of the operative site or the like to the endoscope 11100.

An input device 11204 is an input interface to the endoscopic surgery system 11000. A user can input various types of information and input instructions to the endoscopic surgery system 11000 via the input device 11204. For example, the user inputs an instruction or the like for changing imaging conditions (a type of irradiation light, a magnification, a focal length, and the like) by the endoscope 11100.

A treatment instrument control device 11205 controls driving of the energy treatment instrument 11112 for ablation of a tissue, incision, sealing of a blood vessel, or the like. An insufflator 11206 sends gas into a body cavity through the insufflation tube 11111 in order to inflate the body cavity of the patient 11132 for the purpose of securing a visual field by the endoscope 11100 and securing a working space of the operator. A recorder 11207 is a device capable of recording various types of information regarding the surgery. A printer 11208 is a device capable of printing various types of information regarding the surgery in various forms such as text, images, and graphs.

Note that the light source device 11203 that supplies the endoscope 11100 with irradiation light for capturing an image of the operative site may include, for example, a white light source configured by an LED, a laser light source, or a combination thereof. In a case where the white light source is configured by a combination of RGB laser light sources, since output intensity and output timing of each color (each wavelength) can be controlled with high precision, the light source device 11203 can adjust white balance of a captured image. Furthermore, in this case, it is also possible to capture an image corresponding to each of RGB in a time division manner by irradiating the observation target with laser light from each of the RGB laser light sources in a time-division manner, and controlling driving of the imaging element of the camera head 11102 in synchronization with the irradiation timing. According to this method, it is possible to obtain a color image without providing a filter in the imaging element.

Furthermore, driving of the light source device 11203 may be controlled to change intensity of the light to be outputted at every predetermined time interval. By acquiring images in a time-division manner by controlling the driving of the imaging element of the camera head 11102 in synchronization with the timing of the change of the light intensity, and combining the images, it is possible to generate an image of a high dynamic range without so-called black defects and whiteout.

Furthermore, the light source device 11203 may be configured to be able to supply light having a predetermined wavelength band corresponding to special light observation. In the special light observation, for example, so-called narrow band imaging is performed in which predetermined tissues such as blood vessels in a mucous membrane surface layer are imaged with high contrast by utilizing wavelength dependency of light absorption in body tissues and irradiating the predetermined tissues with narrow band light as compared to the irradiation light (in other words, white light) at the time of normal observation. Alternatively, in the special light observation, fluorescence observation for obtaining an image by fluorescence generated by irradiation of excitation light may be performed. In the fluorescence observation, it is possible to perform irradiating a body tissue with excitation light and observing fluorescence from the body tissue (autofluorescence observation), locally injecting a reagent such as indocyanine green (ICG) into a body tissue and irradiating the body tissue with excitation light corresponding to the fluorescence wavelength of the reagent to obtain a fluorescent image, or the like. The light source device 11203 may be configured to be able to supply narrow band light and/or excitation light corresponding to such special light observation.

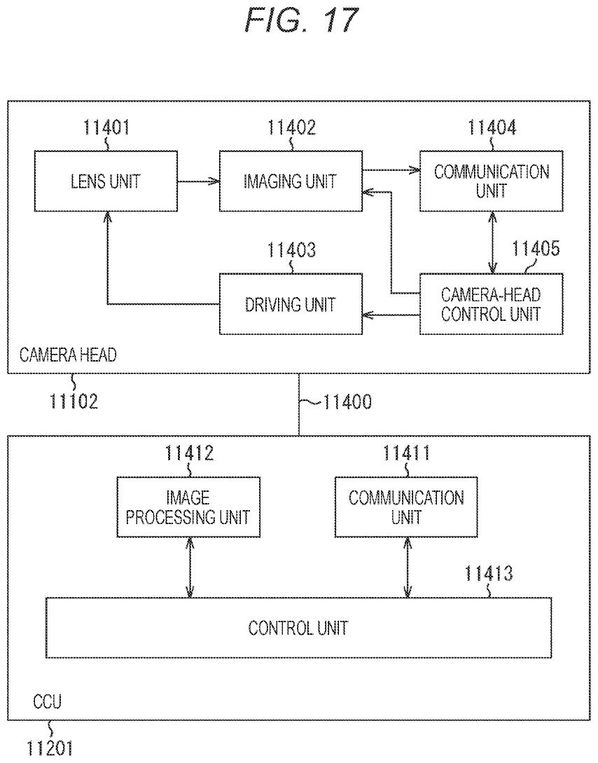

FIG. 17 is a block diagram illustrating an example of a functional configuration of the camera head 11102 and the CCU 11201 illustrated in FIG. 16.

The camera head 11102 has a lens unit 11401, an imaging unit 11402, a driving unit 11403, a communication unit 11404, and a camera-head control unit 11405. The CCU 11201 has a communication unit 11411, an image processing unit 11412, and a control unit 11413. The camera head 11102 and the CCU 11201 are communicably connected in both directions by a transmission cable 11400.

The lens unit 11401 is an optical system provided at a connection part with the lens barrel 11101. Observation light taken in from the distal end of the lens barrel 11101 is guided to the camera head 11102 and is incident on the lens unit 11401. The lens unit 11401 is configured by combining a plurality of lenses including a zoom lens and a focus lens.

The imaging unit 11402 is configured with an imaging device (an imaging element). The number of the imaging elements included in the imaging unit 11402 may be one (a so-called single plate type) or plural (a so-called multi-plate type). In a case where the imaging unit 11402 is configured with the multi-plate type, for example, individual imaging elements may generate image signals corresponding to RGB each, and a color image may be obtained by synthesizing them. Alternatively, the imaging unit 11402 may have a pair of imaging elements for respectively acquiring image signals for the right eye and the left eye corresponding to three-dimensional (3D) display. Performing 3D display enables the operator 11131 to more accurately grasp a depth of living tissues in the operative site. Note that, in a case where the imaging unit 11402 is configured as the multi-plate type, a plurality of systems of the lens unit 11401 may also be provided corresponding to individual imaging elements.

Furthermore, the imaging unit 11402 may not necessarily be provided in the camera head 11102. For example, the imaging unit 11402 may be provided inside the lens barrel 11101 immediately after the objective lens.

The driving unit 11403 is configured by an actuator, and moves the zoom lens and the focus lens of the lens unit 11401 along an optical axis by a predetermined distance under control from the camera-head control unit 11405. With this configuration, a magnification and focus of a captured image by the imaging unit 11402 may be appropriately adjusted.

The communication unit 11404 is configured by a communication device for exchange of various types of information between with the CCU 11201. The communication unit 11404 transmits an image signal obtained from the imaging unit 11402 to the CCU 11201 via the transmission cable 11400 as RAW data.

Furthermore, the communication unit 11404 receives a control signal for controlling driving of the camera head 11102 from the CCU 11201, and supplies to the camera-head control unit 11405. The control signal includes information regarding imaging conditions such as, for example, information of specifying a frame rate of a captured image, information of specifying an exposure value at the time of imaging, information of specifying a magnification and focus of a captured image, and/or the like.

Note that the imaging conditions described above such as a frame rate, an exposure value, magnification, and focus may be appropriately specified by the user, or may be automatically set by the control unit 11413 of the CCU 11201 on the basis of the acquired image signal. In the latter case, a so-called auto exposure (AE) function, auto focus (AF) function, and auto white balance (AWB) function are to be installed in the endoscope 11100.

The camera-head control unit 11405 controls driving of the camera head 11102 on the basis of the control signal from the CCU 11201 received via the communication unit 11404.

The communication unit 11411 is configured by a communication device for exchange of various types of information with the camera head 11102. The communication unit 11411 receives an image signal transmitted via the transmission cable 11400 from the camera head 11102.

Furthermore, the communication unit 11411 transmits, to the camera head 11102, a control signal for controlling driving of the camera head 11102. Image signals and control signals can be transmitted by telecommunication, optical communication, or the like.

The image processing unit 11412 performs various types of image processing on an image signal that is RAW data transmitted from the camera head 11102.

The control unit 11413 performs various types of control related to imaging of an operative site and the like by the endoscope 11100 and related to display of a captured image obtained by the imaging of the operative site and the like. For example, the control unit 11413 generates a control signal for controlling driving of the camera head 11102.

Furthermore, the control unit 11413 causes the display device 11202 to display a captured image in which the operative site or the like is shown, on the basis of the image signal subjected to the image processing by the image processing unit 11412. At this time, the control unit 11413 recognizes various objects in the captured image by using various image recognition techniques. For example, by detecting a shape, a color, and the like of an edge of the object included in the captured image, the control unit 11413 can recognize a surgical instrument such as forceps, a specific living site, bleeding, mist in using the energy treatment instrument 11112, and the like. When causing the display device 11202 to display the captured image, the control unit 11413 may use the recognition result to superimpose and display various types of surgery support information on the image of the operative site. By superimposing and displaying the surgical support information and presenting to the operator 11131, it becomes possible to reduce a burden on the operator 11131 and to allow the operator 11131 to reliably proceed with the surgery.

The transmission cable 11400 connecting the camera head 11102 and the CCU 11201 is an electric signal cable corresponding to communication of an electric signal, an optical fiber corresponding to optical communication, or a composite cable of these.

Here, in the illustrated example, communication is performed by wire communication using the transmission cable 11400, but communication between the camera head 11102 and the CCU 11201 may be performed wirelessly.

An example of the endoscopic surgery system to which the technology according to the present disclosure can be applied has been described above. The technology according to the present disclosure can be applied to the endoscope 11100, (the imaging unit 11402 of) the camera head 11102, and the like among the configurations described above. Specifically, a solid-state imaging device according to the present technology can be applied to the imaging unit 10402. By applying the technology according to the present disclosure to the endoscope 11100, (the imaging unit 11402 of) the camera head 11102, and the like, improvement of performance is enabled.

Here, the endoscopic surgery system has been described as an example, but the technology according to the present disclosure may be applied to other, for example, a microscopic surgery system or the like.

### Application Example 2

### Application Example to Mobile Object

The technology (the present technology) according to the present disclosure can be applied to various products. For example, the technology according to the present disclosure may be realized as a device equipped on any type of mobile objects, such as an automobile, an electric car, a hybrid electric car, a motorcycle, a bicycle, personal mobility, an airplane, a drone, a ship, a robot, and the like.

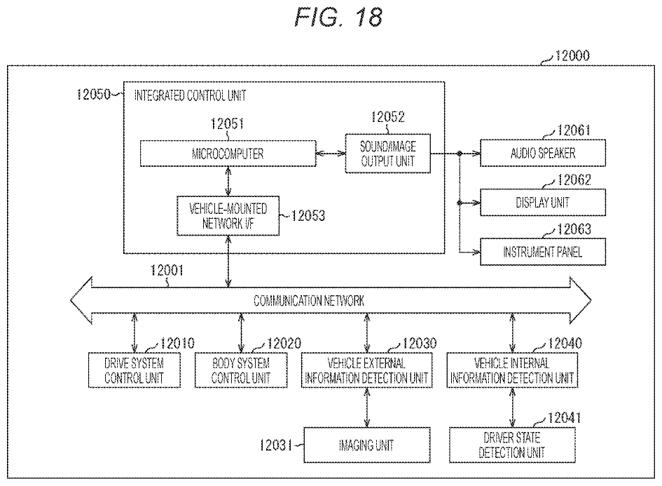

FIG. 18 is a block diagram illustrating a schematic configuration example of a vehicle control system, which is an example of a mobile object control system to which the technology according to the present disclosure may be applied.

A vehicle control system 12000 includes a plurality of electronic control units connected via a communication network 12001. In the example illustrated in FIG. 18, the vehicle control system 12000 includes a drive system control unit 12010, a body system control unit 12020, a vehicle external information detection unit 12030, a vehicle internal information detection unit 12040, and an integrated control unit 12050. Furthermore, as a functional configuration of the integrated control unit 12050, a microcomputer 12051, a sound/image output unit 12052, and a vehicle-mounted network interface (I/F) 12053 are illustrated.

The drive system control unit 12010 controls an operation of devices related to a drive system of a vehicle in accordance with various programs. For example, the drive system control unit 12010 functions as: a driving force generation device for generation of a driving force of the vehicle such as an internal combustion engine or a drive motor; a driving force transmission mechanism for transmission of a driving force to wheels; a steering mechanism to adjust a steering angle of the vehicle; and a control device such as a braking device that generates a braking force of the vehicle.

The body system control unit 12020 controls an operation of various devices mounted on a vehicle body in accordance with various programs. For example, the body system control unit 12020 functions as a control device for a keyless entry system, a smart key system, a power window device, or various lamps such as a headlamp, a back lamp, a brake lamp, a turn indicator, or a fog lamp. In this case, the body system control unit 12020 may be inputted with radio waves or signals of various switches transmitted from a portable device that substitutes for a key. The body system control unit 12020 receives an input of these radio waves or signals, and controls a door lock device, a power window device, a lamp, and the like of the vehicle.

The vehicle external information detection unit 12030 detects information about an outside of the vehicle equipped with the vehicle control system 12000. For example, to the vehicle external information detection unit 12030, an imaging unit 12031 is connected. The vehicle external information detection unit 12030 causes the imaging unit 12031 to capture an image of an outside of the vehicle, and receives the captured image. The vehicle external information detection unit 12030 may perform an object detection process or a distance detection process for a person, a vehicle, an obstacle, a sign, a character on a road surface, or the like on the basis of the received image.

The imaging unit 12031 is an optical sensor that receives light and outputs an electric signal according to an amount of received light. The imaging unit 12031 can output the electric signal as an image, or can output as distance measurement information. Furthermore, the light received by the imaging unit 12031 may be visible light or non-visible light such as infrared light.

The vehicle internal information detection unit 12040 detects information inside the vehicle. The vehicle internal information detection unit 12040 is connected with, for example, a driver state detection unit 12041 that detects a state of a driver. The driver state detection unit 12041 may include, for example, a camera that images the driver, and, on the basis of detection information inputted from the driver state detection unit 12041, the vehicle internal information detection unit 12040 may calculate a degree of tiredness or a degree of concentration of the driver, or may determine whether or not the driver is asleep.

On the basis of information inside and outside the vehicle acquired by the vehicle external information detection unit 12030 or the vehicle internal information detection unit 12040, the microcomputer 12051 can operate a control target value of the driving force generation device, the steering mechanism, or the braking device, and output a control command to the drive system control unit 12010. For example, the microcomputer 12051 can perform cooperative control for the purpose of realizing functions of advanced driver assistance system (ADAS) including avoidance of collisions or mitigation of impacts of the vehicle, follow-up traveling on the basis of an inter-vehicle distance, vehicle speed maintenance traveling, vehicle collision warning, vehicle lane departure warning, and the like.

Furthermore, by controlling the driving force generation device, the steering mechanism, the braking device, or the like on the basis of the information about surroundings of the vehicle acquired by the vehicle external information detection unit 12030 or the vehicle internal information detection unit 12040, the microcomputer 12051 may perform cooperative control for the purpose of, for example, automatic driving for autonomously traveling without depending on an operation of the driver.

Furthermore, the microcomputer 12051 can output a control command to the body system control unit 12020 on the basis of information about the outside of the vehicle acquired by the vehicle external information detection unit 12030. For example, the microcomputer 12051 can control a headlamp in accordance with a position of a preceding vehicle or an oncoming vehicle detected by the vehicle external information detection unit 12030, and perform cooperative control for the purpose of antiglare, such as switching a high beam to a low beam.

The sound/image output unit 12052 transmits an output signal of at least one of sound or an image, to an output device capable of visually or audibly notifying, of information, a passenger of the vehicle or outside the vehicle. In the example of FIG. 18, an audio speaker 12061, a display unit 12062, and an instrument panel 12063 are exemplified as the output devices. The display unit 12062 may include, for example, at least one of an on-board display or a head-up display.

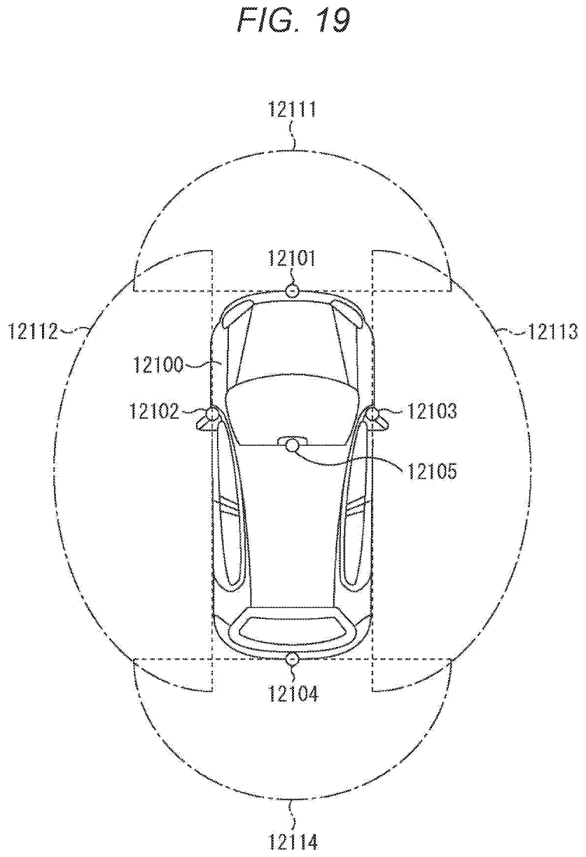

FIG. 19 is a view illustrating an example of an installation position of the imaging unit 12031.

In FIG. 19, as the imaging unit 12031, a vehicle 12100 includes imaging units 12101, 12102, 12103, 12104, and 12105.

The imaging units 12101, 12102, 12103, 12104, and 12105 are provided at, for example, a front nose, side mirrors, a rear bumper, a back door, an upper part of a windshield in a vehicle cabin, or the like of the vehicle 12100. The imaging unit 12101 provided at the front nose and the imaging unit 12105 provided at the upper part of the windshield in the vehicle cabin mainly acquire an image in front of the vehicle 12100. The imaging units 12102 and 12103 provided at the side mirrors mainly acquire an image of a side of the vehicle 12100. The imaging unit 12104 provided at the rear bumper or the back door mainly acquires an image behind the vehicle 12100. A front image acquired by the imaging units 12101 and 12105 is mainly used to detect preceding vehicles, pedestrians, obstacles, traffic lights, traffic signs, lanes, and the like.

Note that FIG. 19 illustrates an example of an image capturing range of the imaging units 12101 to 12104. An imaging range 12111 indicates an imaging range of the imaging unit 12101 provided at the front nose, imaging ranges 12112 and 12113 indicate imaging ranges of the imaging units 12102 and 12103 each provided at the side mirrors, and an imaging range 12114 indicates an imaging range of the imaging unit 12104 provided at the rear bumper or the back door. For example, by superimposing image data captured by the imaging units 12101 to 12104, an overhead view image of the vehicle 12100 viewed from above can be obtained.

At least one of the imaging units 12101 to 12104 may have a function of acquiring distance information. For example, at least one of the imaging units 12101 to 12104 may be a stereo camera including a plurality of imaging elements, or an imaging element having pixels for detecting a phase difference.

For example, on the basis of the distance information obtained from the imaging units 12101 to 12104, by obtaining a distance to each solid object within the imaging ranges 12111 to 12114 and a time change of this distance (a relative speed with respect to the vehicle 12100), the microcomputer 12051 can extract, as a preceding vehicle, especially a solid object that is the closest on a travel route of the vehicle 12100, and that is traveling at a predetermined speed (for example, 0 km/h or more) in substantially the same direction as the vehicle 12100. Moreover, the microcomputer 12051 can set an inter-vehicle distance to be secured from a preceding vehicle in advance, and perform automatic brake control (including follow-up stop control), automatic acceleration control (including follow-up start control), and the like. In this way, it is possible to perform cooperative control for the purpose of, for example, automatic driving for autonomously traveling without depending on an operation of the driver.

For example, on the basis of the distance information obtained from the imaging units 12101 to 12104, the microcomputer 12051 can classify solid object data regarding solid objects into a two-wheeled vehicle, an ordinary vehicle, a large vehicle, a pedestrian, a utility pole, and the like, to extract and use for automatic avoidance of obstacles. For example, the microcomputer 12051 distinguishes obstacles around the vehicle 12100 into obstacles that are visible to the driver of the vehicle 12100 and obstacles that are difficult to see. Then, the microcomputer 12051 can determine a collision risk indicating a risk of collision with each obstacle, and provide driving assistance for collision avoidance by outputting an alarm to the driver via the audio speaker 12061 or the display unit 12062, or by performing forced deceleration and avoidance steering via the drive system control unit 12010, when the collision risk is equal to or larger than a set value and there is a possibility of collision.

At least one of the imaging units 12101 to 12104 may be an infrared camera that detects infrared light. For example, the microcomputer 12051 can recognize a pedestrian by determining whether or not a pedestrian exists in a captured image of the imaging units 12101 to 12104. Such recognition of a pedestrian is performed by, for example, a procedure of extracting a feature point in a captured image of the imaging unit 12101 to 12104 as an infrared camera, and a procedure of performing pattern matching processing on a series of feature points indicating a contour of an object and determining whether or not the object is a pedestrian. When the microcomputer 12051 determines that a pedestrian is present in the image captured by the imaging units 12101 to 12104 and recognizes the pedestrian, the sound/image output unit 12052 controls the display unit 12062 so as to superimpose and display a rectangular contour line for emphasis on the recognized pedestrian. Furthermore, the sound/image output unit 12052 may control the display unit 12062 to display an icon or the like indicating a pedestrian at a desired position.

An example of the vehicle control system to which the technology (the present technology) according to the present disclosure can be applied has been described above. The technology according to the present disclosure can be applied to, for example, the imaging unit 12031 and the like among the configurations described above. Specifically, a solid-state imaging device according to the present technology can be applied to the imaging unit 12031. By applying the technology according to the present disclosure to the imaging unit 12031, performance can be improved.

Note that the present technology is not limited to the above-described embodiments, usage examples, and application examples, and various modifications can be made without departing from the scope of the present technology.

Note that the effects described in this specification are merely examples and are not limited, and other effects may also be present.

Note that the present technology can have the following configurations.

[1] A solid-state imaging device including:

a first substrate on which a pixel unit configured to perform photoelectric conversion is formed; and

a second substrate on which a logic circuit configured to process a pixel signal outputted from the pixel unit is formed, in which

the first and second substrates are laminated by being connected by metal binding between wiring layers that are formed individually,

an opening hole is formed on an outer periphery of the pixel unit to penetrate the first and second substrates to reach an upper part of a wire bonding pad formed in the second substrate,

the second substrate includes an insulating layer below the wire bonding pad, and

the insulating layer includes a first insulating film.

[2] The solid-state imaging device according to [1], in which

the insulating layer further includes a second insulating film,

the insulating layer is configured by alternately laminating the first insulating film and the second insulating film in a downward direction,

a part of the first insulating film is formed on the wire bonding pad side from a center of a length of the insulating layer in a downward direction, and

hardness of the first insulating film is higher than hardness of the second insulating film.

[3] The solid-state imaging device according to [2], in which

the insulating layer is configured by alternately laminating a plurality of first insulating films and one or more second insulating films in a downward direction,

a part of the first insulating film that is at least one of the plurality of first insulating films is formed on the wire bonding pad side from a center of a length of the insulating layer in a downward direction, and

hardness of the first insulating film is higher than hardness of each of the second insulating film.

[4] The solid-state imaging device according to any one of [1] to [3], in which

the first insulating film includes a Si nitride film having a nitrogen content of 13 mass % or more and a carbon content of 13 mass % or more.

[5] The solid-state imaging device according to any one of [1] to [4], in which

the first insulating film includes a Si nitride film having a nitrogen content of 50 mass % or more.

[6] The solid-state imaging device according to any one of [2] to [5], in which

the second insulating film includes a Si oxide film having a nitrogen content of 0 to 5 mass %.

[7] The solid-state imaging device according to any one of [2] to [6], in which

the insulating layer is configured by laminating a first insulating film and a second insulating film in this order.

[8] The solid-state imaging device according to any one of [2] to [7], in which

the insulating layer is configured by laminating a second insulating film, a first insulating film, and a second insulating film in this order.

[9] The solid-state imaging device according to any one of [2] to [8], in which

the insulating layer is configured by laminating a first insulating film, a second insulating film, and a first insulating film in this order.

[10] The solid-state imaging device according to any one of [2] to [9], in which

the insulating layer is configured by laminating a second insulating film, a first insulating film, a second insulating film, a first insulating film, a second insulating film, and a first insulating film in this order.

[11] The solid-state imaging device according to any one of [2] to [10], in which

the insulating layer is configured by laminating a first insulating film, a second insulating film, a first insulating film, a second insulating film, and a first insulating film in this order.

[12] The solid-state imaging device according to any one of [2] to [11], in which

the insulating layer is configured by laminating a second insulating film, a first insulating film, a second insulating film, and a first insulating film in this order.

[13] The solid-state imaging device according to any one of [2] to [12], in which

the insulating layer is configured by laminating a first insulating film, a second insulating film, and a first insulating film in this order.

[14] The solid-state imaging device according to any one of [2] to [13], in which

the insulating layer is configured by laminating a second insulating film, a second insulating film, and a first insulating film in this order.

[15] An electronic device equipped with the solid-state imaging device according to any one of [1] to [14].

### REFERENCE SIGNS LIST

10 Solid-state imaging device
1 First substrate
11 First silicon substrate
12 First wiring layer
14 Pixel unit
15 On-chip lens
16 Color filter
2 Second substrate
21 Second silicon substrate
22 Second wiring layer
24 Pad
201 First insulating layer
202 Second insulating layer
203 Third insulating layer
211 First insulating film
212 Second insulating film
3 Bonding surface
4 Wire
5 Opening hole

1. A solid-state imaging device comprising:
a first substrate on which a pixel unit configured to perform photoelectric conversion is formed; and
a second substrate on which a logic circuit configured to process a pixel signal outputted from the pixel unit is formed, wherein
the first and second substrates are laminated by being connected by metal binding between wiring layers that are formed individually,
an opening hole is formed on an outer periphery of the pixel unit to penetrate the first and second substrates to reach an upper part of a wire bonding pad formed in the second substrate,
the second substrate includes an insulating layer below the wire bonding pad, and
the insulating layer includes a first insulating film.

2. The solid-state imaging device according to claim 1, wherein
the insulating layer further includes a second insulating film,
the insulating layer is configured by alternately laminating the first insulating film and the second insulating film in a downward direction,
a part of the first insulating film is formed on the wire bonding pad side from a center of a length of the insulating layer in a downward direction, and
hardness of the first insulating film is higher than hardness of the second insulating film.

3. The solid-state imaging device according to claim 2, wherein
the insulating layer is configured by alternately laminating a plurality of first insulating films and one or more second insulating films in a downward direction,
a part of the first insulating film that is at least one of the plurality of first insulating films is formed on the wire bonding pad side from a center of a length of the insulating layer in a downward direction, and
hardness the first insulating films is higher than hardness of each of the second insulating film.

4. The solid-state imaging device according to claim 1, wherein
the first insulating film includes a Si nitride film having a nitrogen content of 13 mass % or more and a carbon content of 13 mass % or more.

5. The solid-state imaging device according to claim 1, wherein
the first insulating film includes a Si nitride film having a nitrogen content of 50 mass % or more.

6. The solid-state imaging device according to claim 2, wherein
the second insulating film includes a Si oxide film having a nitrogen content of 0 to 5 mass %.

7. The solid-state imaging device according to claim 2, wherein
the insulating layer is configured by laminating a first insulating film and a second insulating film in this order.

8. The solid-state imaging device according to claim 2, wherein
the insulating layer is configured by laminating a second insulating film, a first insulating film, and a second insulating film in this order.

9. The solid-state imaging device according to claim 2, wherein
the insulating layer is configured by laminating a first insulating film, a second insulating film, and a first insulating film in this order.

10. The solid-state imaging device according to claim 2, wherein
the insulating layer is configured by laminating a second insulating film, a first insulating film, a second insulating film, a first insulating film, a second insulating film, and a first insulating film in this order.

11. The solid-state imaging device according to claim 2, wherein
the insulating layer is configured by laminating a first insulating film, a second insulating film, a first insulating film, a second insulating film, and a first insulating film in this order.

12. The solid-state imaging device according to claim 2, wherein
the insulating layer is configured by laminating a second insulating film, a first insulating film, a second insulating film, and a first insulating film in this order.

13. The solid-state imaging device according to claim 2, wherein
the insulating layer is configured by laminating a first insulating film, a second insulating film, and a first insulating film in this order.

14. The solid-state imaging device according to claim 2, wherein
the insulating layer is configured by laminating a second insulating film, a second insulating film, and a first insulating film in this order.

15. An electronic device equipped with the solid-state imaging device according to claim 1.
